(19) United States
(12) Patent Application Publication
(10) Pub. No.: US 2015/0159271 A1
(43) Pub. Date: Jun. 11, 2015

(54) DEPOSITION OF NON-ISOSTRUCTURAL LAYERS FOR FLEXIBLE SUBSTRATE

(71) Applicant: Veeco ALD Inc., Fremont, CA (US)

(72) Inventors: Sang In Lee, Los Altos Hills, CA (US); Chang Wan Hwang, Hwaseong-si (KR)

(21) Appl. No.: 14/561,513

(22) Filed: Dec. 5, 2014

Related U.S. Application Data
(60) Provisional application No. 61/913,686, filed on Dec. 9, 2013.

(51) Int. Cl. C23C 16/455; C23C 16/52; C23C 16/22

(52) U.S. Cl. CPC C23C 16/45525; C23C 16/22; C23C 16/52

(57) ABSTRACT

A plurality of non-isostructural layers are deposited onto a substrate. An inorganic layer is deposited onto the substrate by adsorbing metal atoms to the substrate. The inorganic layer on the substrate is exposed to a hydrocarbon-containing source precursor to deposit a first hydrocarbon-containing layer by adsorbing the hydrocarbon-containing source precursor onto the inorganic layer. The first hydrocarbon-containing layer on the substrate is exposed to a reactant precursor to increase reactivity of the first hydrocarbon-containing layer on the substrate, and a second hydrocarbon-containing layer is deposited onto the first hydrocarbon-containing layer on the substrate. The process may be repeated to deposit the plurality of layers. The second hydrocarbon-containing layer may have higher hydrocarbon content and may be deposited at a higher deposition rate than the first hydrocarbon-containing layer.

### CROSS-REFERENCE TO RELATED APPLICATION

This application claims the benefit of U.S. Provisional Patent Application No. 61/913,686, filed Dec. 9, 2013, which is hereby incorporated by reference in its entirety.

### BACKGROUND

1. Field of Art

The disclosure relates to the deposition of multiple layers (“multilayers”) of non-isostructural material onto a substrate for encapsulation.

2. Description of the Related Art

Flexible substrates are employed in various electronic devices such as organic light emitting diode (OLED) devices and other display devices. Such devices include a flexible substrate on which multiple layers of devices, organic layers, and inorganic layers are placed. One or more layers of organic and/or inorganic layers may be formed to enclose devices or other layers to prevent ambient species from coming into contact with the devices or other active components. By preventing contact with the ambient species, a structure having good operating characteristics and long shelf life can be fabricated. The ambient species may include oxidizing agents (e.g., water, oxygen, carbon dioxide) and reducing agents (e.g., hydrogen or carbon monoxide).

Flexible display devices may be bent a single time or multiple times into different shapes. As the flexible substrate and the materials formed on the substrate are bent, the flexible substrate and the materials on the substrate are subject to stress. The increased stress may lead to cracks in the flexible substrate or materials formed on the flexible substrate. Such cracks may propagate and cause the flexible substrate or devices formed thereon to experience shortened lifespan or degraded performance.

### SUMMARY

Embodiments relate to a method of depositing a plurality of non-isostructural layers onto a substrate and to the product produced by the same method. An inorganic layer is deposited onto the substrate by adsorbing metal atoms to the substrate. The inorganic layer on the substrate is exposed to a hydrocarbon-containing source precursor to deposit a first hydrocarbon-containing layer, which is deposited onto the inorganic layer by adsorbing the hydrocarbon-containing source precursor to the inorganic layer. This process may be repeated to form a plurality of inorganic layers and first hydrocarbon-containing layers on the substrate with covalent bonds between the inorganic and hydrocarbon-containing layers formed by an adsorption mechanism. To deposit the inorganic layer, the substrate may be exposed to a metal-containing source precursor to adsorb metal atoms such as aluminum, zirconium, tin, titanium, and nickel onto the substrate, and the substrate may be exposed to the reactant precursor. A plurality of inorganic layers may be deposited by repeating these steps.

In some embodiments, the first hydrocarbon-containing layer on the substrate is exposed to a reactant precursor to increase a deposition rate of the first hydrocarbon-containing layer onto the substrate or to increase the reactivity of the precursor, and a second hydrocarbon-containing layer is deposited onto the first hydrocarbon-containing layer on the substrate before repeating the process to deposit the inorganic layer. To deposit the second hydrocarbon-containing layer, the first-hydrocarbon-containing layer is exposed to the hydrocarbon-containing source precursor, and the substrate is exposed to the reactant precursor to increase the reactivity of the hydrocarbon-containing source precursor or to increase the number of adsorption sites. A plurality of second hydrocarbon-containing layers may be deposited by repeating these steps.

In some embodiments the first hydrocarbon-containing layer and the second hydrocarbon layers are deposited by exposing the substrate to different hydrocarbon-containing source precursors. In some embodiments, the first hydrocarbon-containing layer is deposited at a first deposition rate and the second hydrocarbon-containing layer is deposited at a second deposition rate exceeding the first deposition rate.

In some embodiments, the first deposited hydrocarbon-containing layer is subject to one of tensile stress and compressive stress, and the deposited inorganic layer is subject to another of the tensile stress and the compressive stress. In some embodiments, the inorganic layer has a first thickness, the first hydrocarbon-containing layer and the second hydrocarbon-containing layer together have a second thickness, and a ratio of the first thickness to the second thickness is between 67:33 and 40:60. In some embodiments, the ratio of the first thickness to the second thickness is less than 87:13. In some embodiments, the first hydrocarbon-containing layer has a lower hydrocarbon content than the second hydrocarbon-containing layer.

In some embodiments, the first hydrocarbon-containing layer and/or the second hydrocarbon layer include at least one of a metalcone, a hydrocarbon-containing ceramic, and a hydrocarbon-containing ceramic oxide. In some embodiments, the hydrocarbon-containing source precursor includes at least one of a silane coupling agent and a silicon-containing precursor. In some embodiments, the reactant precursor includes radicals generated from an oxidizing agent or a reducing agent.

### BRIEF DESCRIPTION OF DRAWINGS

FIG. 1 is a cross-sectional diagram of conventional isostructural multilayers formed on a substrate.

FIGS. 2A through 2C are cross-sectional diagrams of non-isostructural multilayers formed on a substrate, according to various embodiments.

FIG. 3 is a flowchart illustrating an overall process of forming non-isostructural multilayers on a substrate, according to one embodiment.

FIG. 4 is a flowchart illustrating deposition of an inorganic layer onto the substrate, according to one embodiment.

FIG. 5 is a flowchart illustrating deposition of a hydrocarbon-containing layer onto the substrate, according to one embodiment.

FIG. 6 is a conceptual diagram illustrating a series of reactors placed over a moving substrate for injecting precursors onto the substrate, according to one embodiment.

FIGS. 7A through 7D are cross-sectional diagrams of various forms of non-isostructural multilayers on a substrate, according to various embodiments.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to forming non-isostructural layers of material on a substrate by using atomic layer deposition (ALD) or molecular layer deposition (MLD). Non-isostructural layers include one or more layers of inorganic material (e.g., Al₂O₃) and one or more layers of hydrocarbon-containing material. The layers of hydrocarbon-containing material may be placed between the layers of inorganic material to function as a barrier layer having short-range ordering polymer network to absorb dislocation motion and to prevent the growth of cracks in the brittle inorganic material. The bond between layers including interfaces of the inorganic materials and the hydrocarbon-containing materials is a covalent bond. The inorganic material and the hydrocarbon-containing material may be stacked to form an encapsulation layer of a desired thickness. The relative thicknesses of the inorganic material and the hydrocarbon-containing material may be chosen to reduce stress exerted on the substrate by the non-isostructural layers.

Non-isostructural layers refer to layers having a plurality of layers having different structures and different physical properties such as Young's modulus, particularly adjacent layers having different structures. For example, an inorganic layer has a crystalline structure, and an adjacent hydrocarbon-containing layer has an amorphous structure or a crystalline structure based on a crystalline lattice having a different Young's modulus from the inorganic layer's crystalline lattice.

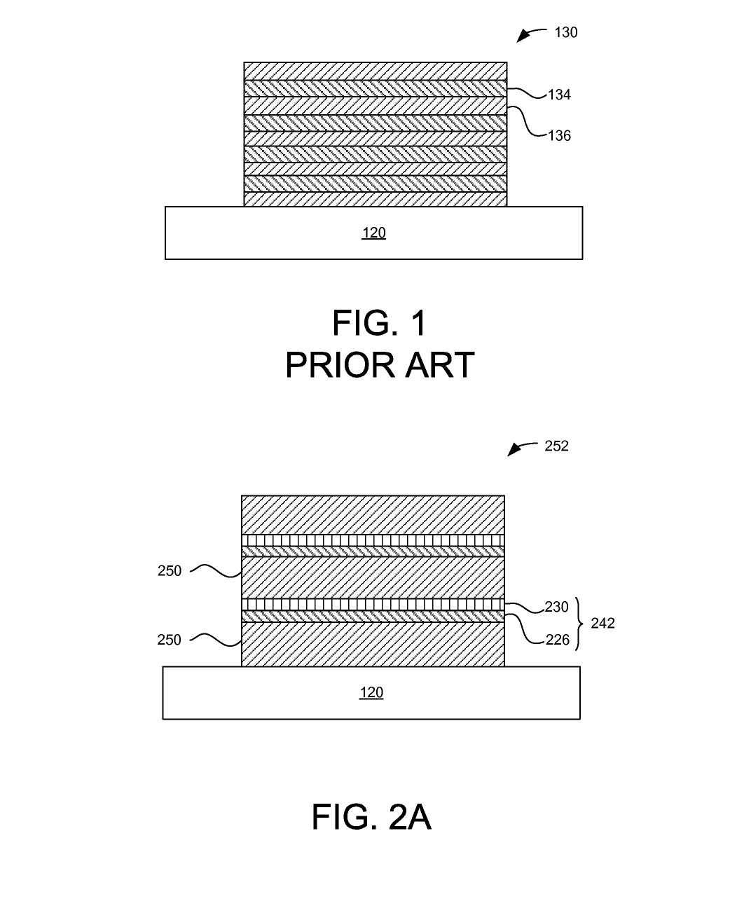

FIG. 1 is a cross-sectional diagram of conventional isostructural multilayers 130 formed on a substrate 120. The isostructural multilayers 130 include alternating layers of a first inorganic material 136 having a tensile stress and a second inorganic material 134 having a tensile stress. For example, the first inorganic material 136 is Al₂O₃ film and the second inorganic material 134 is SiO₂ or ZrO₂, which are deposited using an atomic layer deposition (ALD) process. Using two different types of tensile-stressed inorganic materials in alternating layers may reduce the number of pinholes or defects by decoupling the growth of pinholes or defects, and hence, improves barrier properties relative to a single type of inorganic material. However, these layers of inorganic materials are similar to a single layer of inorganic material in terms of physical and mechanical properties and also do not prevent dislocation motion because these inorganic layers are brittle and tensile-stressed films. Both the brittleness of the inorganic layer and the lack of a barrier to block dislocation motion may exceed the yield stress of the material and contribute to the formation and propagation of cracks when the substrate 120 and the multilayers 130 are bent.

### Non-Isostructural Multilayers

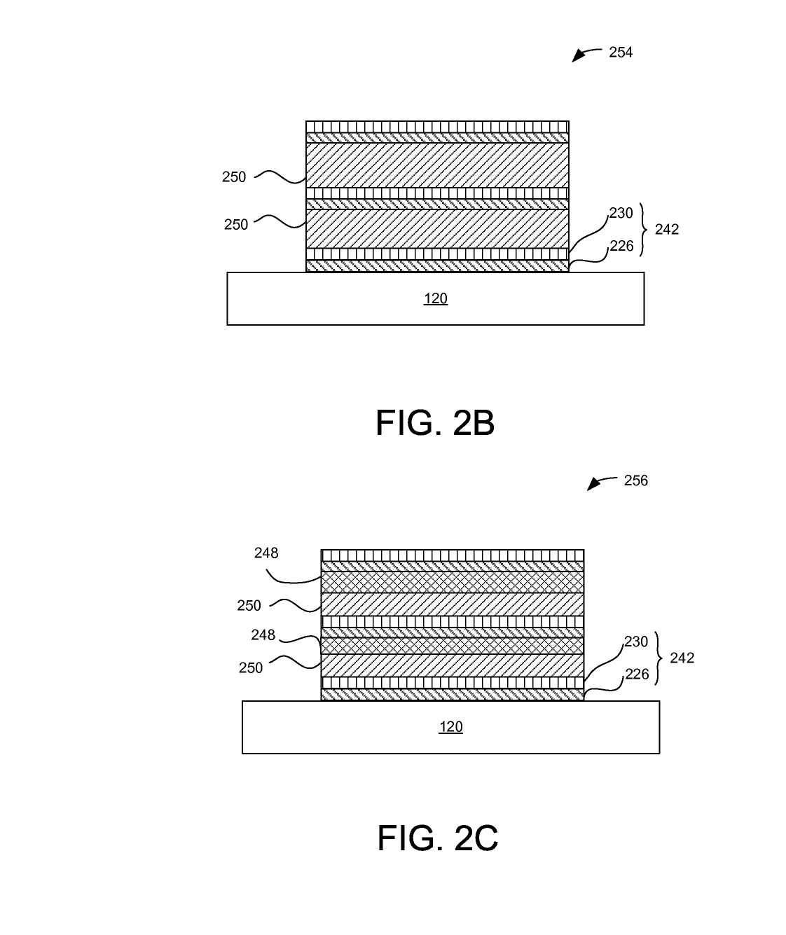

FIG. 2A is a cross-sectional diagram of non-isostructural multilayers 252 formed on a substrate 120, according to one embodiment. The non-isostructural multilayers 252 include one or more inorganic layers 250 of an inorganic material, one or more layers 226 of a first hydrocarbon-containing material, and one or more layers 230 of a second hydrocarbon-containing material. A first hydrocarbon-containing layer 226 is formed below a second hydrocarbon-containing layer 230. The first hydrocarbon-containing layer 226 and the second hydrocarbon-containing layer 230 collectively form a barrier layer 242 to prevent the propagation of cracks through the layers 250 of inorganic material.

The inorganic material enables stacking of layers of hydrocarbon-containing materials on the substrate 120 using an ALD process. The inorganic material may be a ceramic (e.g., aluminum oxide Al₂O₃, silicon dioxide SiO₂, silicon nitride Si₃N₄, silicon oxynitride SiOₓN_{y}, titanium dioxide TiO₂, zirconium dioxide ZrO₂, tin oxide SnO₂, nickel oxide NiO). To deposit a conductive stacking of layers of hydrocarbon-containing materials, inorganic material may be either a conducting oxide (e.g., Indium Tin Oxide (In, Sn)Oₓ, ruthenium oxide RuO₂, Iridium oxide Ir₂O₃, Perovskite oxide such as RuSrO₃) or a transition metal-nitride (e.g. titanium nitride TiN, tantalum nitride TaN, or nickel nitride NiN), or graphene. Typically, the inorganic material is essentially free of hydrocarbons. The inorganic material or precursor material for depositing the inorganic material may also function as catalyst for increasing the deposition rate of the hydrocarbon-containing material.

The hydrocarbon-containing material has a different structure and a different dislocation slip system compared to the inorganic material. In one embodiment, the first and second layers of hydrocarbon-containing materials may be of the same material. The hydrocarbon-containing material may be, for example, a hydrocarbon-containing ceramic or hydrocarbon-containing ceramic oxide (e.g., hydrocarbon-containing silicon oxide SiOCH, hydrocarbon-containing titanium oxide TiOCH, hydrocarbon-containing zirconium oxide ZrOCH), or hydrocarbon-containing ceramic carbide (e.g., hydrocarbon-containing silicon carbide SiCH, SiCNH), or hydrocarbon-containing ceramic nitride (e.g., hydrocarbon-containing silicon carbide SiNH, SiCNH), or a hydrocarbon-containing film such as a metalcone (e.g., Alucone, Zircone, Zincone) deposited using molecular layer deposition (MLD). SiOCH (and other carbon-containing ceramics) have a higher polymeric characteristic and is ductile compared to an inorganic material such as Al₂O₃ or SiO₂. Such characteristics enable the hydrocarbon-containing material to function as a barrier layer 242 to prevent occurrence and propagation of cracks in the multilayers 250. Alternatively, the first and second layers of hydrocarbon-containing materials may be of different material. For example, the first hydrocarbon-containing layer 226 and second hydrocarbon-containing layer 230 are, respectively, SiOCH and Alucone, SiOCH and Zircone, ZrOCH and Alucone, or TiOCH and Zincone. Combining a first hydrocarbon-containing layer 226 that is a hydrocarbon-containing ceramic oxide with a second hydrocarbon-containing layer 230 that is a metalcone beneficially increases the flexibility, robustness, and yield strength of the resulting multilayers 250 compared to hydrocarbon-containing layers of metalcone or hydrocarbon-containing ceramic oxide alone.

It is also to be noted that the layers are sequentially stacked with multiple layers of the inorganic material layer 250, the first hydrocarbon-containing layer 226, and the second hydrocarbon-containing layer 230 of hydrocarbon-containing material. Different materials in the multilayers 250 may be subject to tensile or compressive stress. By sequentially stacking the materials in sequence, the tensile or compressive stress present in each layer of material may counteract bending force exerted on the substrate 120 and therefore reduce or prevent crack formation.

When depositing a layer of Al₂O₃ as the inorganic material and SiOCH as the hydrocarbon-containing material, it is advantageous to use trimethylaluminum (TMA) as the metal-containing source precursor of Al₂O₃ since the TMA may function as a catalyst that increases the deposition rate of the SiOCH layer and the deposition rate of the transition metal oxides as well.

FIG. 2B is a cross-sectional diagram illustrating non-isostructural multilayers 254 formed on a substrate 120, according to another embodiment. In the embodiment of FIG. 2B, a sandwich-structured multilayer 254 is disclosed. The sandwich-structured multilayer 254 includes layers 250 of the inorganic material (e.g., Al₂O₃) sandwiched between (i.e., deposited between) the hydrocarbon-containing layers 242. Further hydrocarbon-containing barrier layers 242 may be sandwiched between successive layers 250 of the inorganic material with covalent bonds at each interface.

FIG. 2C is a cross-sectional diagram illustrating non-isostructural multilayers 256 formed on a substrate 120, according to yet another embodiment. The multilayers 256 are different from the multilayers 254 in that layers 248 of another inorganic material (e.g., ZrO₂) are deposited on layers 250 of the inorganic material. Due to the different densities of the two different inorganic layers, the growth of pinholes or defects is decoupled or at least deterred. Thus, layers 248 and 250 of two inorganic materials are successively deposited between barrier layers 242.

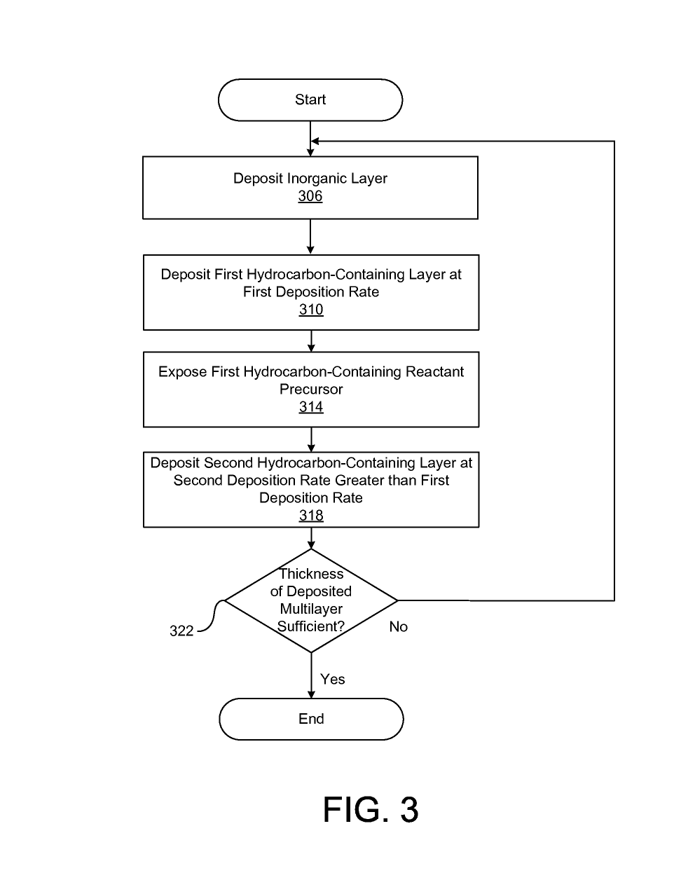

Although the following embodiments describe primarily forming multilayers 252 of FIG. 2A with reference to FIGS. 3 through 7D, the same principles can be applied to formation of multilayers 254, 256, or other non-isostructural multilayers not specifically described herein.

### Formation of Non-Isostructural Multilayers

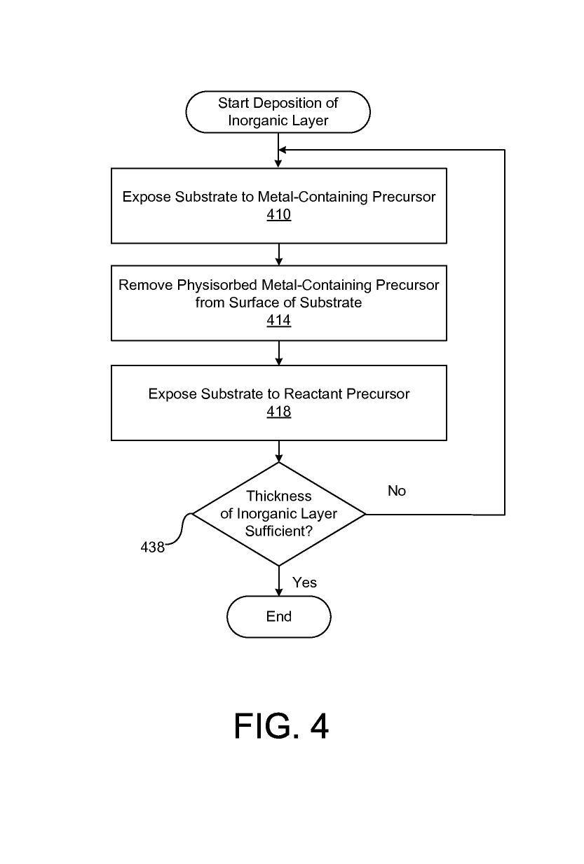

FIG. 3 is a flowchart illustrating an overall process of forming the non-isostructural multilayers 252 on a substrate 120, according to one embodiment. A layer 250 of inorganic material (e.g., Al₂O₃) is deposited 306 on the substrate 120, as described below in detail with reference to FIG. 4.

After depositing the layer 250 of the inorganic material, a first hydrocarbon-containing layer 226 of hydrocarbon-containing layer (e.g., SiOCH) is deposited 310 on the inorganic layer 250 at a first deposition rate. If, for example, the first hydrocarbon-containing layer 226 is SiOCH, then the substrate 120 is exposed to silicon-containing organic precursor (e.g., aminophenyltrimethoxysilane (APTMOS)) to deposit the first hydrocarbon-containing layer 226. Then, the substrate 120 may be purged by passing inert gas (e.g., argon) over the substrate 120 to remove excess physisorbed organic precursor molecules from the surface of the substrate 120. Then, the substrate 120 is exposed to a reactant precursor such as radicals (e.g., O* radicals or H* radicals) that increase the reactivity of the first hydrocarbon-containing layer 226 with a subsequent layer. As a result, a mono-layer of SiOCH is formed on the substrate 120.

Alternatively to exposing the substrate 120 to a silicon-containing organic precursor to deposit 310 the first layer 226, the substrate 120 is exposed 310 a titanium-containing organic precursor or a zirconium-containing organic precursor to deposit 310 the first layer 226.

Subsequently, the first hydrocarbon-containing layer 226 is exposed 314 to reactant precursor. The reactant precursor may include radicals of an oxidizing agent (e.g., O* radicals from oxygen gas), radicals of a reducing agent (e.g., H* radicals from hydrogen gas or ammonia), or radicals of a nitriding agent (e.g., N* radicals from nitrogen gas or ammonia). For example, the radicals are produced from plasma of the oxidizing agent, reducing agent, or nitriding agent. The exposure 314 to radicals appears to increase the rate of subsequent deposition of the second hydrocarbon-containing layer 230 of hydrocarbon-containing layer on the first hydrocarbon-containing layer 226.

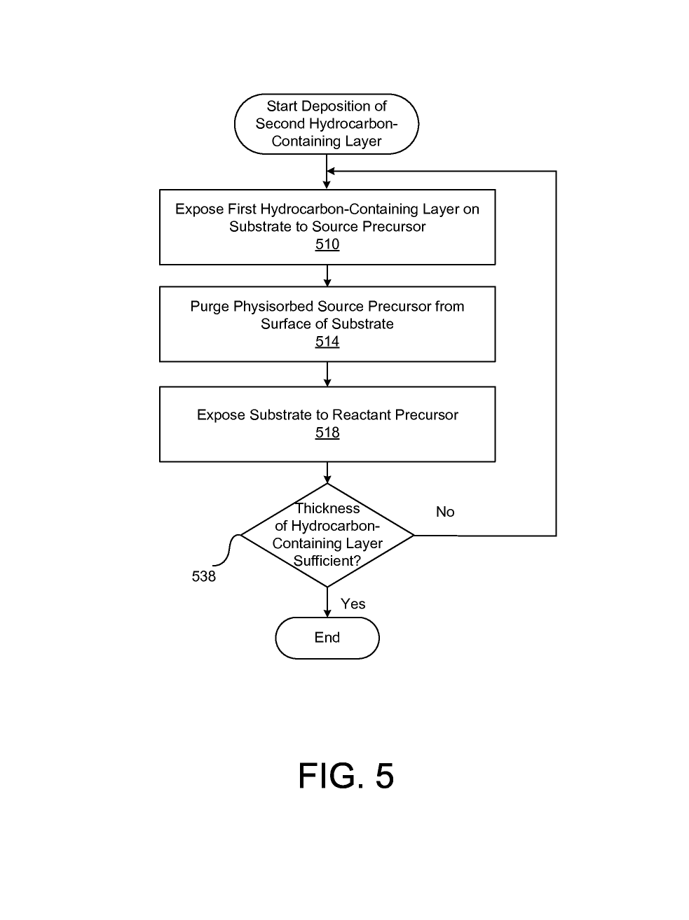

Then, a second hydrocarbon-containing layer 230 is deposited 318 on the first hydrocarbon-containing layer 226 at a second deposition rate that is higher than the first deposition rate, as described below in detail with reference to FIG. 5. The exposure 314 of first hydrocarbon-containing layer 226 to radicals increases the rate of deposition to form the second hydrocarbon-containing layer 230.

It is then determined 322 whether the thickness of the deposited multilayers is sufficient (e.g., whether the thickness exceeds a threshold thickness). If the thickness of the deposited multilayers is sufficient (e.g., the thickness exceeds the threshold thickness), then the process terminates. If the thickness of the deposited multilayers is insufficient (e.g., the thickness does not exceed the threshold thickness), the process returns to depositing 306 the first inorganic layer and repeats the subsequent processes until multilayers 252 of a sufficient thickness are obtained.

### Deposition of Inorganic Layer

FIG. 4 is a flowchart illustrating deposition of the inorganic layer 250 onto the substrate 120, according to one embodiment. The inorganic layer 250 may be deposited using atomic layer deposition (ALD) or any other deposition methods. First, the substrate 120 is exposed 410 to a metal-containing source precursor such as trimethylaluminum (TMA) to adsorb metal atoms of the metal-containing source precursor onto the substrate. The physisorbed molecules of the metal-containing source precurs may be removed 414 by a purge gas (e.g., an inert gas).

Then the substrate 120 is exposed 418 to reactant precursor. The reactant precursor may be, for example, O* radicals or radicals of another oxidizing agent such as water H₂O plasma, nitrous oxide and ammonia (N₂O+NH₃) plasma, oxygen and hydrogen (O₂+H₂) plasma, or ozone and hydrogen (O₃+H₂) plasma. The reactant precursor may be, for example, N* radicals or radicals of another nitriding agent such as nitrogen N₂ plasma, ammonia NH₃ plasma, or nitrogen and hydrogen (N₂+H₂) plasma. As a result of exposure to the reactant precursor and a purge gas (e.g., an inert gas, not shown in FIG. 4), the inorganic layer 250 is deposited on the substrate 120. In one embodiment, the inorganic layer 250 is an atomic layer.

It is then determined 438 whether the thickness of the inorganic layer 250 is sufficient (e.g., whether the thickness exceeds a threshold thickness). If the thickness is sufficient (e.g., the thickness exceeds the threshold thickness), then the process of depositing the inorganic layer terminates. If the thickness is insufficient (e.g., the thickness does not exceed the threshold thickness), then the process proceeds to exposing 410 the substrate 120 to the metal-containing source precursor to repeat the process to deposit additional inorganic material onto the substrate 120.

### Deposition of Second Hydrocarbon-Containing Layer

FIG. 5 is a flowchart illustrating deposition of a second hydrocarbon-containing layer 230 onto the substrate 120, according to one embodiment. The hydrocarbon-containing layer 230 is deposited using ALD or molecular layer deposition (MLD), for example. First, the first hydrocarbon-containing layer 226 on the substrate 120 is exposed 510 to a hydrocarbon-containing source precursor. The hydrocarbon-containing source precursor may be a silane coupling agent (e.g., APTMOS, 3-aminopropyl triethoxy silane (APTEOS), 3-aminopropyl dimethylethoxy silane (APDMEOS)) or a silicon-containing precursor (e.g., tri-diethylaminosilane (TDMAS)). The hydrocarbon-containing source precursor for TiOCH or ZrOCH may be a tetrakisdimethylamidotitanium (TDMAT) or tetrakisdimethylamidozirconium (TDMAZ).

After injecting the source precursor, physisorbed source precursor molecules are purged 514 from the substrate 120 using a purge gas (e.g., argon gas). Then the substrate 120 is exposed 518 to reactant precursor. The reactant precursor may be, for example, O* radicals or H* radicals. If APTMOS or TDMAS are used as the hydrocarbon-containing source precursor and O* radicals are used as the reactant precursor, a layer of SiOCH is formed on the substrate 120 as the second hydrocarbon-containing layer 230.

Then it is determined 538 whether the thickness of the hydrocarbon-containing layer is sufficient (e.g., whether the thickness exceeds a threshold thickness). If the thickness is sufficient (e.g., the thickness exceeds the threshold thickness), then the process terminates. If the thickness is insufficient (e.g., the thickness does not exceed the threshold thickness), the process returns to exposing 510 the substrate 120 the hydrocarbon-containing source precursor and repeating the process to deposit additional hydrocarbon-containing material onto the substrate 120.

### Example Deposition Device

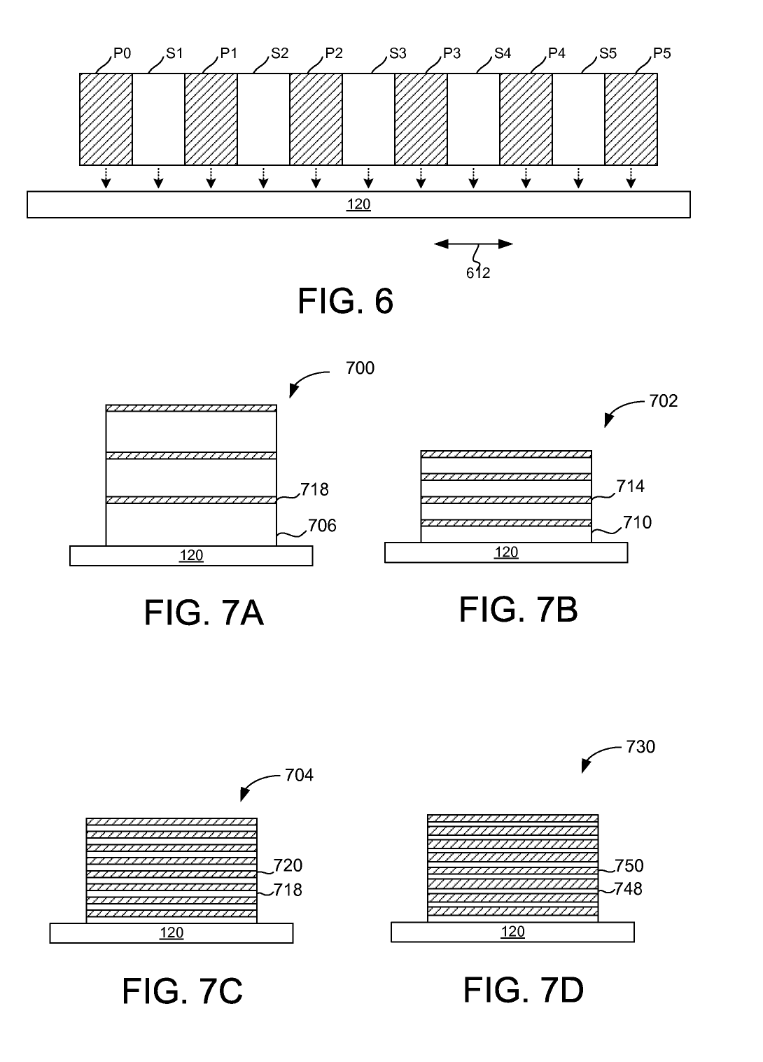

FIG. 6 is a conceptual diagram illustrating a series of reactors placed over a moving substrate 120 for injecting precursors onto the substrate 120, according to one embodiment. The substrate 120 may be placed in a susceptor (not shown) that moves the substrate 120 relative to the series of reactors. The path of relative movement may be linear as illustrated, or the path of relative movement may be circular when the reactors are arranged around an axis of the susceptor's rotation relative to the reactors (not illustrated). In the embodiment of FIG. 6, the reactors P0 through P5 and S1 through S5 are arranged in tandem and configured to inject precursor materials onto the substrate 120 as the substrate 120 moves below the reactors (as indicated by arrow 612). Reactors P0 through P5 generate reactant precursor such as radicals and inject the reactant precursor onto the substrate 120. The reactors S1 through S5 inject one or more types of source precursor (e.g., hydrocarbon-containing source precursor, metal-containing precursor) onto the substrate 120.

In one embodiment, the substrate 120 makes a reciprocating movement below the reactors, as shown by arrow 612. As the substrate 120 moves from left to right, the substrate 120 sequentially passes below the reactors P0, S1, P1, S2, P2, S3, P3, S4, P4, S5, and P5. If the substrate 120 moves from the right to the left, the substrate 120 sequentially passes below the reactors P5, S5, P4, S4, P3, S3, P2, S2, P1, S1, and P0.

The reactors P0 through P5 and S1 through S5 may be configured to receive different gases or generate different radicals by switching of gases injected into these reactors.

In a first example, reactors S1 through S4 inject TMA onto the substrate 120 and reactor S5 injects APTMOS onto the substrate 120. Nitrous oxide gas N₂O is injected into the reactors P0 through P5 that expose the substrate 120 to O* radicals generated from the N₂O. When the substrate 120 passes below the set of the reactors from left to right, four atomic layers of Al₂O₃ and one mono-layer of SiO₂ or SiOCH of low hydrocarbon content are sequentially deposited on the substrate 120. The layer of SiO₂ or SiOCH of low hydrocarbon content is deposited at a relatively slow rate when the substrate 120 is moving from the left to the right.

Continuing the first example, when the substrate 120 completes its movement from left to right, the substrate 120 is then moved from right to left below the reactors. As a result, the previously deposited layer of SiO₂ or SiOCH of low hydrocarbon content is exposed to O* radicals by the reactor P5 and then injected with APTMOS. Due to the activation by the O* radicals of the previously deposited layer of SiO₂ or SiOCH of low hydrocarbon content, the exposure to APTMOS causes adsorption of more APTMOS onto the SiO₂ or SiOCH of low hydrocarbon content, and thereby causes deposition of SiOCH of high hydrocarbon content onto the substrate 120 at a relatively higher rate. As the substrate 120 continues moving from right to left, four additional layers of Al₂O₃ are deposited onto the substrate 120.

To summarize the first example, a reciprocating cycle of the substrate 120 movement causes deposition of eight atomic layers of Al₂O₃ layers and two mono-layers of SiOCH (i.e., one mono-layer of SiOCH with low hydrocarbon content and one mono-layer of SiOCH with high hydrocarbon content). Specifically, two mono-layers of SiOCH are deposited between two sets of Al₂O₃ layers, each set including four layers of Al₂O₃.

In a second example, reactors S1 and S5 inject APTMOS onto the substrate 120 while reactors S2 through S4 inject TMA onto the substrate 120. N₂O gas is injected into the reactors P0 through P5, which expose the substrate 120 to O* radicals generated from the N₂O gas. When the substrate 120 passes below the series of reactors from left to right, a bottom layer of SiO₂ or SiOCH with low hydrocarbon content is deposited on the substrate 120, and then three atomic layers of Al₂O₃ and one top mono-layer of SiO₂ or SiOCH with low hydrocarbon content are deposited onto the substrate 120. The layers of SiO₂ or SiOCH with low hydrocarbon content are deposited at a slower deposition rate than the layers of SiO₂ or SiOCH with high hydrocarbon content.

Continuing the second example, when the end of the substrate 120's movement from left to right is reached, the substrate 120 is again moved from right to left below the reactors. As a result, the substrate 120 is exposed to O* radicals by the reactor P5 and then injected with APTMOS by the reactor S5. Due to activation of the top layer of SiO₂ or SiO₂ with low hydrocarbon content by the O* radicals injected by the reactor P5, the exposure to APTMOS causes more APTMOS to be adsorbed onto the layer of SiO₂ or SiOCH with low hydrocarbon content, and thereby causes a layer of SiOCH layer of high hydrocarbon content to be deposited on the substrate 120 at a higher deposition rate. As the substrate 120 continues moving from right to left, the substrate 120 is deposited with an additional three atomic layers of Al₂O₃ and a subsequent mono-layer of SiOCH.

To summarize the second example, a reciprocating cycle of the substrate 120 movement causes deposition of six atomic layers of Al₂O₃ and four mono-layers of SiOCH (i.e. two layers of low-hydrocarbon-content SiOCH layer and two layers of high-hydrocarbon-content SiOCH).

In a third example, reactors S2 and S3 inject APTMOS onto the substrate 120 while reactors S1, S4, and S5 inject TMA onto the substrate 120. In this example, an additional reactor P2′ is installed between S2 and S3, adjacent to reactor P2′ in series. N₂O gas is injected into reactors P2′ and P0 through P5, which expose the substrate 120 to O* radicals generated in the reactors P2′ and P0 through P5. When the substrate 120 passes below the set of the reactors from the left to the right, a bottom inorganic layer of Al₂O₃, first and second hydrocarbon-containing layers of SiOCH, and two top inorganic layers of Al₂O₃ are formed on the substrate 120. The second hydrocarbon-containing layer of SiOCH is deposited at a higher deposition rate than the first SiOCH layer.

When the substrate 120 completes its movement from left to right, the substrate 120 is again moved from right to left below the reactors. As a result, one inorganic atomic layer of Al₂O₃, two hydrocarbon-containing mono-layers of SiOCH, and two inorganic atomic layers of Al₂O₃ are sequentially deposited on the substrate 120.

To summarize the third example, a reciprocating cycle of the substrate 120 movement causes six atomic layers of Al₂O₃ layers and four mono-layers of SiOCH to be deposited on the substrate 120.

Depositing a layer of SiOCH above another layer of SiOCH or SiO₂ layer in the above examples is advantageous, among other reasons, because the second layer of SiOCH can be deposited at a higher deposition rate than the first layer of SiOCH or SiO₂.

Although the above examples use O* radicals as reactant precursor to deposit SiOCH layers on the substrate 120, radicals generated from a reducing agent (e.g., H* radicals) radicals generated from another oxidizing agent, or other radicals may also be used. When H* radicals are used, a process akin to MLD is performed. That is, H* radicals are used as reactant precursor in steps 314 and 518 to deposit a material such as aluminum hydride as an intermediate material. The deposited material has polymeric characteristics and therefore functions to prevent or reduce occurrence and propagation of cracks in the multilayers.

The use of a vapor deposition reactor with the reactors as illustrated in FIG. 6 is advantageous, among other reasons, because the inorganic layer and the hydrocarbon-containing material can be deposited using the same device. By using the same vapor deposition reactor to deposit different layers on the substrate 120, the overall deposition process can be performed in a more efficient manner because (i) process time for moving the substrate 120 between different deposition equipments or devices can be eliminated, (ii) the overall size of the deposition equipment can be reduced, and (iii) the number of particles leaked during transfer of the substrate 120 between different deposition devices can be reduced.

### Effect of Relative Thickness on Stress in Substrate

FIG. 7A is a cross-sectional diagram of non-isostructural multilayers 700 of a first combination formed on a substrate 120, according to one embodiment. In one experiment, a set of multilayers 700 with a thickness of 305.2 Å was formed on a silicon substrate 120. The multilayers 700 included layers 706 of Al₂O₃ and layers 718 of SiOCH stacked in an alternating manner so that two mono-layers 718 of SiOCH were formed for every ten atomic layers 706 of Al₂O₃. The relative thicknesses of the atomic layers 706 of Al₂O₃ layers and the mono-layers 718 of SiOCH layers were 87:13. In the experiment, a tensile stress of 221 MPa was observed at the silicon substrate 120 on which the multilayers 702 were formed, which is a smaller tensile stress than is found for an ALD aluminum oxide Al₂O₃ layer, where a tensile stress of 280 MPa occurs at the same thickness. In addition, the film stress was less than the tensile and/or compressive stress of the inorganic layer 706 of Al₂O₃.

FIG. 7B is a cross-sectional diagram of non-isostructural multilayers 702 of a second combination formed on a substrate 120, according to one embodiment. To deposit non-isostructural multilayers 702, a set of multilayers 702 with a thickness of 297.4 Å was formed on a substrate 120. The multilayers 702 included Al₂O₃ layers 710 and SiOCH layers 714 stacked in an alternating manner so that two layers 714 of SiOCH were formed for every four layers 710 of Al₂O₃. The relative thicknesses of the layers 710 of Al₂O₃ and the layers 714 of SiOCH were 73:27. In this experiment, almost zero film stress was observed, but a tensile stress of 58 MPa was observed at the substrate 120 on which the multilayers 702 were formed.

FIG. 7C is a cross-sectional diagram of non-isostructural multilayers 704 of a third combination formed on a substrate 120, according to one embodiment. To deposit non-isostructural multilayers 704, a set of multilayers 704 with a thickness of 303.1 Å was formed. The multilayers 704 included layers 718 of Al₂O₃ layers 720 of SiOCH. The multilayers 704 were formed by depositing a single layer 718 of Al₂O₃ and a single layer 720 of SiOCH in an alternating manner. The relative thicknesses of layers 718 of Al₂O₃ and layers 720 of SiOCH were 67:33. In this experiment, almost zero film stress was observed, but a compressive stress of 89 MPa was observed at a substrate 120 on which the multilayers 704 were formed.

FIG. 7D is a cross-sectional diagram of non-isostructural multilayers 730 of a third combination formed on a substrate 120, according to one embodiment. To deposit non-isostructural multilayers 702, a set of multilayers 730 with a thickness of 300.5 Å was formed. The multilayers 730 included layers 748 of Al₂O₃ and layers 750 of SiOCH. The multilayers 704 were formed by depositing a single layer 748 of Al₂O₃ and two layers 750 of SiOCH layers in an alternating manner. The relative thicknesses of layers 748 of Al₂O₃ and layers 750 of SiOCH layers were 40:60. In this experiment, a compressive stress of 195 MPa was observed at a substrate 120 on which the multilayers 730 were formed.

Based on the above experiments, the stress in the substrate 120 may be reduced by using atomic layers of Al₂O₃ and SiOCH, where the thickness ratio of layers of Al₂O₃ to layers of SiOCH is less than 87:13, or where the ratio of the number of the atomic layers of Al₂O₃ to the number of atomic layers of SiOCH is less than 10:2. These ratios reduce the tensile stress compared to a single layer of Al₂O₃, and even may induce compressive stress at a Al₂O₃ to SiOCH layer thickness ratio of 40:60. Further, no cracks were formed by a bending test when layers of Al₂O₃ and SiOCH were deposited on 150 μm thick polyethylene-naphthalate (PEN) film (used as substrate 120), but cracks were formed by the same bending test when a single Al₂O₃ layer was deposited on the same PEN film.

The reduction of tensile stress or compressive stress at the substrate 120 is preferable, among other reasons, because thicker layers of material may be deposited on the substrate 120 without causing the substrate 120 to bend due to the stress, and the deposited layer is less likely to peel off from the substrate 120.

Instead of reducing the tensile or inducing compressive stress, the thickness of an inorganic layer (e.g., Al₂O₃) and the thickness of the hydrocarbon-containing layers may be adjusted to induce a certain degree of compressive stress (or to modify tensile stress) in the substrate 120 or the deposited layer. In the above example of a combination of layers of Al₂O₃ and SiOCH, the thickness of layers of Al₂O₃ relative to layers of SiOCH may be decreased to reduce the tensile stress or increase the compressive stress on the substrate 120. Conversely, the thickness of the layers of Al₂O₃ to the layers of SiOCH may be increased to increase the tensile stress or decrease the compressive stress on the substrate 120. By adjusting the relative thickness of the inorganic layers and the hydrocarbon-containing layers, the tensile or compressive stress in the substrate 120 can be tuned as desired.

The multilayers of inorganic material and hydrocarbon-containing material may be used for purposes including, among others, encapsulation of devices formed on a flexible substrate 120, gas permeable coatings on a wrap paper for food packaging with increased strength in high moisture environment (e.g., immersed in water), and separators for a flexible lithium-ion-battery.

What is claimed is:

1. A method for depositing a plurality of non-isostructural layers onto a substrate, the method comprising:
(a) depositing an inorganic layer onto the substrate, the inorganic layer comprising metal atoms adsorbed to the substrate;
(b) exposing the inorganic layer on the substrate to a hydrocarbon-containing source precursor to deposit a first hydrocarbon-containing layer by adsorbing the hydrocarbon-containing source precursor onto the inorganic layer; and
(c) repeating (a) and (b) to form a plurality of layers of inorganic layers and first hydrocarbon-containing layers on the substrate.

2. The method of claim 1, wherein the first deposited hydrocarbon-containing layer is subject to one of tensile stress and compressive stress, and the deposited inorganic layer is subject to another of the tensile stress and the compressive stress.

3. The method of claim 1, further comprising:
(d) exposing the first hydrocarbon-containing layer on the substrate to a reactant precursor to increase reactivity of the first hydrocarbon-containing layer on the substrate; and
(e) depositing a second hydrocarbon-containing layer onto the first hydrocarbon-containing layer by adsorbing a second hydrocarbon-containing source precursor onto the first hydrocarbon-containing layer before repeating (a) to deposit the inorganic layer.

4. The method of claim 3, wherein the first hydrocarbon-containing layer has a lower hydrocarbon content than the second hydrocarbon-containing layer.

5. The method of claim 3, wherein depositing the second hydrocarbon-containing layer comprises:
(d1) exposing the first-hydrocarbon-containing layer to the second hydrocarbon-containing source precursor to deposit the second hydrocarbon-containing layer by adsorbing the second hydrocarbon-containing source precursor onto the first hydrocarbon-containing layer; and
(d2) exposing the substrate to the reactant precursor to increase reactivity of the deposited second hydrocarbon-containing layer.

6. The method of claim 5, wherein depositing the inorganic layer onto the substrate further comprises repeating (d1) and (d2) to deposit additional second hydrocarbon-containing layers onto the second hydrocarbon-containing layer on the substrate.

7. The method of claim 3, wherein the inorganic layer has a first thickness, the first hydrocarbon-containing layer and the second hydrocarbon-containing layer together have a second thickness, and a ratio of the first thickness to the second thickness is less than 87:13.

8. The method of claim 3, wherein the inorganic layer is a first number of atomic layers, the first hydrocarbon-containing layer and the second hydrocarbon-containing layer are together a second number of atomic layers, and a ratio of the first number of atomic layers to the second number of atomic layers is less than 10:2.

9. The method of claim 3, wherein the first hydrocarbon-containing layer is deposited at a first deposition rate and the second hydrocarbon-containing layer is deposited at a second deposition rate exceeding the first deposition rate.

10. The method of claim 3, wherein depositing the second hydrocarbon-containing layer comprises:
(d1) exposing the first hydrocarbon-containing layer to another hydrocarbon-containing source precursor to deposit the second hydrocarbon-containing layer by adsorbing the other hydrocarbon-containing source precursor onto the first hydrocarbon-containing layer, the other hydrocarbon-containing source precursor different from the hydrocarbon-containing source precursor; and
(d2) exposing the substrate to the reactant precursor to increase reactivity of the deposited second hydrocarbon-containing layer.

11. The method of claim 1, wherein depositing the inorganic layer comprises:
(a1) exposing the substrate to a metal-containing source precursor to adsorb the metal atoms onto the substrate; and
(a2) exposing the substrate to the reactant precursor.

12. The method of claim 11, wherein depositing the inorganic layer onto the substrate further comprises repeating (a1) and (a2) to deposit additional inorganic layers onto the inorganic layer on the substrate.

13. The method of claim 1, wherein the first hydrocarbon-containing layer comprises at least one of: a metalcone, a hydrocarbon-containing ceramic oxide, a hydrocarbon-containing ceramic nitride, a hydrocarbon-containing conductive nitride, and a hydrocarbon-containing ceramic carbide.

14. The method of claim 1, wherein the hydrocarbon-containing source precursor comprises at least one of: a silane coupling agent and a silicon-containing precursor.

15. A product comprising a plurality of non-isostructural layers deposited onto a substrate, the product produced by a method comprising:
(a) depositing an inorganic layer onto the substrate, the inorganic layer comprising metal atoms adsorbed to the substrate;
(b) exposing the inorganic layer on the substrate to a hydrocarbon-containing source precursor to deposit a first hydrocarbon-containing layer by adsorbing the hydrocarbon-containing source precursor onto the inorganic layer; and
(c) repeating (a) and (b) to form a plurality of layers of inorganic layers and first hydrocarbon-containing layers on the substrate.

16. The product of claim 15, wherein the first deposited hydrocarbon-containing layer is subject to one of tensile stress and compressive stress, and the deposited inorganic layer is subject to another of the tensile stress and the compressive stress.

17. The product of claim 15, wherein the method further comprises:
(d) exposing the first hydrocarbon-containing layer on the substrate to a reactant precursor to increase reactivity of the first hydrocarbon-containing layer on the substrate; and
(e) depositing a second hydrocarbon-containing layer onto the first hydrocarbon-containing layer by adsorbing a second hydrocarbon-containing source precursor onto the first hydrocarbon-containing layer before repeating (a) to deposit the inorganic layer.

18. The product of claim 17, wherein the first hydrocarbon-containing layer has a lower hydrocarbon content than the second hydrocarbon-containing layer.

19. The product of claim 17, wherein the inorganic layer has a first thickness, the first hydrocarbon-containing layer and the second hydrocarbon-containing layer together have a second thickness, and a ratio of the first thickness to the second thickness is less than 87:13.

20. The product of claim 17, wherein the inorganic layer is a first number of atomic layers, the first hydrocarbon-containing layer and the second hydrocarbon-containing layer are together a second number of atomic layers, and a ratio of the first number of atomic layers to the second number of atomic layers is less than 10:2.
